(19) United States
(12) Patent Application Publication
(10) Pub. No.: US 2018/0269388 A1
(43) Pub. Date: Sep. 20, 2018

(54) PHASE CHANGE MEMORY UNIT AND PREPARATION METHOD THEREFOR

(71) Applicant: SHANGHAI INSTITUTE OF MICROSYSTEM AND INFORMATION TECHNOLOGY, CHINESE ACADEMY OF SCIENCES, Shanghai (CN)

(72) Inventors: ZHITANG SONG, Shanghai (CN); KUN REN, Shanghai (CN); FENG RAO, Shanghai (CN); SANNIAN SONG, Shanghai (CN); BANGNING CHEN, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 15/739,900

(22) PCT Filed: Apr. 14, 2014
(86) PCT No.: PCT/CN2014/075276

§ 371 Date: May 28, 2018

(30) Foreign Application Priority Data
Jul. 19, 2013 (CN) 201310306025.X

(51) Int. Cl. H01L 45/00

(52) U.S. Cl. CPC H01L 45/06; H01L 45/1616; H01L 45/148; H01L 45/1253; H01L 45/144; H01L 45/1675

(57) ABSTRACT

A phase change memory cell and a preparation method thereof. A phase change material layer having a thickness equal to the size of a single unit cell or a plurality of unit cells is adopted, the phase change material layer fundamentally expresses interfacial characteristics, and body material characteristics are weakened, such that a two-dimensional phase change memory cell storing information through change of interface resistance and having a high density, low power consumption and high speed is prepared. Since the phase change material layer according to the present invention is thin and there are a small number of defects on an interface of the phase change material layer, the operation power consumption of the phase change memory cell is reduced, the operation time of the phase change memory cell is shortened, the damage to a phase change material during each operation process is reduced, the element segregation effect on the material during each operation process is decreased, the maximum operability number of times of the phase change memory cell is increased, and therefore the capacity of circulating operation number of times of a device can be increased.

### TECHNICAL FIELD

The present invention belongs to technical field of microelectronics, and relates to a phase change memory cell and a preparation method thereof. More particularly, the present invention relates to a two-dimensional phase change memory cell having high density, low power consumption and high speed, and a preparation method thereof.

### BACKGROUND

Phase Change Random Access Memory (PCRAM) uses Joule heat generated by the operation signal to operate the phase change material, such that the phase change material changes between different phases, thereby reflecting the difference between high and low resistance values and completing the storage of information. Phase change memory is considered to be one of the most promising next-generation non-volatile memories because of its fast operation speed, good data retention, strong cycling operation capability, compatibility with traditional CMOS processes, and the ability to maintain its operation performance in small size.

Phase change materials are information storage medium of phase change memory, and characteristics of the phase change materials such as thermal stability, solid phase stability, crystallization speed and melting point have direct influences on data retention, cycle operating life, operating speed and operating power consumption of the phase change memory. Thus, the performance of the phase change memory can be directly improved by choosing excellent phase change material. GeSbTe material is the most widely used phase change material, and its most important feature is that its performances are balanced in all aspects. GeSbTe is a kind of phase change material which is dominated by nucleation and crystallization, and it shows a uniform and stable crystalline phase with data retention of 90° C. for ten years, melting point of 630° C. and crystallization speed of about 50 nanoseconds. The GeTe phase change material is a kind of phase change material which is dominated by growth crystallization, and it shows a uniform and stable crystal phase with data retention of 100° C. for ten years and the crystallization speed can reach 1 nanosecond. The disadvantage of GeTe is the higher melting point, i.e., 730° C. TiSbTe is a new kind of phase change material which is dominated by growth crystallization, and it shows a uniform and stable crystal phase with data retention of 110° C. for ten years, the crystallization speed can reach 6 nanoseconds and the melting point is 540° C. TiSbTe is a very promising material. The above three kinds of materials have good electrical operating performances when being used as phase change memory devices, and are the preferred materials when manufacturing phase change memory.

The above three kinds of phase change materials are of diamond crystal lattice structure when they are in crystalline state. The distance between adjacent atoms is about 6 angstrom. The literature (nature doi: 10.1038/nmat1215) reported that the phase change of GST involves only the jump of Ge atoms between different positions. The unit where Ge atoms are located is a cube with three atoms as side length, and the side length is about 6 angstrom. It can be regarded that the size of the cube is the minimum size to change the phase, and the cube is the smallest phase change unit. In order to complete the phase change, sizes in any dimensionalities of the phase change materials must be more than 6 Angstrom.

The effective part of the operating power consumption is the energy to achieve the phase change of the phase change material. The smaller the phase change region is, the smaller the required energy and the lower the power consumption of the device will be. The restrictive structure phase change memory reduces operating power consumption of the device by reducing the phase change region. The purpose of preparing small-sized electrodes, such as the blade structure and the ring structure, is to reduce the phase change region and thereby reduce the power consumption. However, the device resistances of the above structures are mainly determined by the resistances of the phase change material film.

Contact resistance is the resistance generated at the interface where the phase change material is in contact with metal electrode. The value of the contact resistance is proportional to the contact resistivity and is inversely proportional to the contact area. Wherein, the contact resistivity is determined by the material on both sides of the interface, which is the essential property of the interface. The smaller the contact area is, the larger the contact resistance will be. The literature (APPLIED PHYSICS LETTERS 102, 213503 (2013)) reported that the contact resistivity of the interface where the amorphous phase change material GST is in contact with the TiN is 1.58×10⁷ Ω·μm², which is almost 1000 times as the contact resistivity, i.e., 1.74×10⁴ Ω·μm², at the interface between the crystalline GST and TiN.

The contact resistance between the phase change material and the metal electrode accounts for a small proportion in the overall resistance of the conventional phase change memory cell, and is much smaller than the proportion of the resistance provided by the phase change material film. The literature (APPLIED PHYSICS LETTERS 102, 213503 (2013)) points out that the reason that the contact resistance accounts for a small proportion is that a crystalline phase change material layer remains at the interface. Since the RESET state of the traditional phase change memory only needs to form an amorphous region in the phase change material to block the crystalline low-resistance path between the top and bottom electrodes. Because the metal electrode having high thermal conductivity dissipates heat rapidly, the temperature of the phase change material at the interface during the RESET operation is always below the melting point, thereby a crystalline phase change material layer remains in the interface. The interface between the crystalline state phase change material layer and the metal electrode has been maintained at a low-resistance state during SET and RESET operation, the influence on the total resistance of the device unit is small. At the same time, literature (APPLIED PHYSICS LETTERS 102, 213503 (2013)) also pointed out that the contact resistance between the phase change material in amorphous state and the metal electrode is about 1000 times as the contact resistance between the phase change material in a crystalline state and the metal resistance, which can significantly affect the resistance value of the device and the required strength of operating signals.

The main reason that the phase change memory loses efficacy is the reduced material uniformity result from element segregation of the phase change material. The element diffusion occurs mainly under high temperature conditions generated by current when operation. The longer the high temperature keeps, the serious the element segregation will be. Therefore, operating the phase change material in a high power for a long time will promote the element segregation, speed up device failure and reduce the number of recyclable operations.

On the contrary, because the operation time of the phase change memory with low power consumption and rapid operation is short, the segregation effect of the material for each operation is low, cycle times of the operation of the device will be improved. Therefore, how to prepare a phase change memory having characteristics of low power consumption and fast operation is a technical problem to be urgently solved.

### SUMMARY

In view of the above disadvantages of the prior art, an object of the present invention is to provide a phase change memory cell and a preparation method thereof for solving the failure problem of the phase change memory caused by high power consumption and slow operation speed of the phase change memory cell in the prior art.

In order to achieve the above object and other related objects, the present invention provides a preparation method of a phase change memory cell, the preparation method comprises at least the following steps:

1) providing a Si substrate having a surface on which a first dielectric material layer is formed, and successively forming a lower electrode layer and a second dielectric material layer on the first dielectric material layer from bottom to top;

2) photo-etching and etching a portion of the second dielectric material layer until the lower electrode layer is exposed so as to form a window;

3) depositing a phase change material on a surface of the structure obtained in step 2) to form a phase change material layer having a first thickness;

4) removing a portion of the phase change material layer located on the lower electrode layer to divide the phase change material layer into two portions so as to respectively provide phase change material layers for a pair of phase change memory cells;

5) depositing a third dielectric material layer on a surface of the structure obtained in step 4) to simultaneously fill up the window and isolate the phase change material layer divided into two portions in step 4);

6) flattening the structure obtained in step 5) with a chemical mechanical polishing process until the first dielectric material layer and a portion of the phase change material layer are exposed, such that the phase change material layer has two opposite L-shaped cross sections;

7) forming an upper electrode layer covering the exposed phase change material layer.

Optionally, the thickness of the first dielectric material layer ranges from 2 nm to 10 nm.

Optionally, the opening width of the window ranges from 10 nm to 100 nm.

Optionally, the first thickness ranges from 6 angstrom to 60 angstrom, such that the phase change memory cell stores information by using the interfacial resistance difference of the phase change material layer.

Optionally, the first thickness ranges from 6 angstrom to 20 angstrom.

Optionally, the length of the phase change material layer ranges from 50 angstrom to 100 angstrom, and the width of the phase change material layer ranges from 50 angstrom to 100 angstrom.

Optionally, the phase change material comprises at least one of Ge—Sb—Te, Ge—Te and Ti—Sb—Te.

Optionally, the unit driving device for realizing the reading/writing/erasing function of the phase change memory cell comprises a transistor or a diode, wherein when the unit driving device is a transistor, an 1T1R structure is formed; when the unit driving device is a diode, an 1D1R structure is formed.

The present invention further provides a phase change memory cell, and the phase change memory cell comprises:

a Si substrate;

a first dielectric material layer formed on a surface of the Si substrate;

a lower electrode layer formed on a surface of the first dielectric material layer;

a second dielectric material layer, a phase change material layer and a third dielectric material layer, all of which having upper surfaces located in a same plane, being formed on the lower electrode layer, and being in contact with the lower electrode layer, wherein the phase change material layer having a first thickness isolates the second dielectric material layer from the third dielectric material layer;

an upper electrode layer being in contact with the phase change material layer.

Optionally, the phase change material layer has two opposite L-shaped cross sections isolated by the third dielectric material layer, wherein one side of the L-shaped cross sections being in contact with the lower electrode layer is a first side, and the other side of the L-shaped cross sections being perpendicular to the first side is a second side, the thicknesses of both the first side and the second side are the first thickness.

Optionally, the first thickness ranges from 6 angstrom to 60 angstrom, such that the phase change memory cell stores information by using the interfacial resistance difference of the phase change material layer.

Optionally, the first thickness ranges from 6 angstrom to 20 angstrom.

The present invention further provides a preparation method of phase change memory cell, and the preparation method at least comprises the following steps:

1) providing a Si substrate having a surface on which a second dielectric material is formed, and preparing an electrode pair on the second dielectric material layer, wherein a distance between the electrode pair is a first distance;

2) depositing a phase change material on a surface of the structure obtained in step 1) to form a phase change material layer having a first thickness;

3) photoetching and etching the phase change material layer to form a phase change material layer having a width less than or equal to the width of the electrode pair,

4) depositing a third dielectric material layer on a surface of the structure obtained in step 3) and filling up the area between the electrode pair.

Optionally, the first thickness ranges from 6 angstrom to 60 angstrom, such that the phase change memory cell stores information by using the interfacial resistance difference of the phase change material layer.

Optionally, the first thickness ranges from 6 angstrom to 20 angstrom.

Optionally, the first distance ranges from 10 nm to 100 nm.

Optionally, the thickness of the third dielectric material layer ranges from 20 nm to 100 nm.

Optionally, the material of the electrode pair is metal, metal alloy, metal nitride or graphene; the metal is Ti, W, Pt and the like; the metal alloy is the alloy composed of Ti, W, Pt and the like; the metal nitride is TiN, TaN and the like.

The present invention further provides a phase change memory cell, and the phase change memory cell comprises:

a Si substrate;

a second dielectric material layer formed on a surface of the Si substrate;

a electrode pair formed on a surface of the second dielectric material layer and having a first distance therebetween;

a phase change material layer formed on surfaces of the electrode pair and the second dielectric material layer, having a width less than or equal to the width of the electrode pair and having a first thickness;

a third dielectric material layer formed on surfaces of the phase change material layer and the electrode pair, or formed on a surface of the phase change material layer.

Optionally, the first thickness ranges from 6 angstrom to 60 angstrom, such that the phase change memory cell stores information by using the interfacial resistance difference of the phase change material layer.

Optionally, the first thickness ranges from 6 angstrom and 20 angstrom.

Optionally, the first distance ranges from 10 nm to 100 nm.

Optionally, the thickness of the third dielectric material layer ranges from 20 nm to 100 nm.

Optionally, the material of the electrode pair is metal, metal alloy, metal nitride or graphene; the metal is Ti, W, Pt and the like; the metal alloy is the alloy composed of Ti, W, Pt and the like; the metal nitride is TiN, TaN and the like.

As described above, the phase change memory cell and the preparation method thereof according to the present invention have the following beneficial effects:

According to the phase change memory cell of the present invention, the thickness of the used phase change material layer is equal to the dimension of a single unit cell or a plurality of unit cells. On one hand, the phase change region is reduced, and on the other hand, the body material characteristics of the phase change material layer are weakened. In addition, the reversible phase change behavior of the phase change material layer is focus on the interfacial characteristics. Therefore, the two-dimensional phase change memory cell having high density, low power consumption and high speed and storing information by using resistance variation of the interface is prepared. In the present invention, due to the thin phase change material layer and the small amount of defects on the interface of the phase change material layer, the operating power consumption of the phase change memory cell is reduced and the operating time is shortened, thereby reducing the damage to the phase change material during each operation. Thus, the element segregation effect on the material during each operation is reduced and the maximum number of operation of the phase change memory cell is increased, thereby enhancing the cycle number of operations. Further, the graphene electrode used in the present invention has features of fast signal response, high mechanical strength and less energy loss. Thus, the phase change memory cell based on graphene electrode has the advantages of high speed, low power consumption and long service life.

The reversible phase change behavior of the small amount of unit cells of the phase change material layer in the present invention, the close and similar behaviors of amorphous basic unit and polycrystalline basic unit, the behavior of interface defects, the behavior of large difference between the metal and the phase change material in the amorphous and the polycrystalline resistances are compatible with the new kind of CMOS, and offers tremendous power in high speed, low power consumption under technical nodes of 10 nanometers.

### BRIEF DESCRIPTION OF THE DRAWINGS

FIGS. 1A to 1G are structural diagrams showing corresponding steps of a phase change memory cell and a preparation method thereof in embodiment one according to the present invention, wherein FIG. 1G is also a structural diagram showing a pair of phase change memory cells in Embodiment one.

FIGS. 2A to 2D are structural diagrams showing corresponding steps of a phase change memory cell and a preparation method thereof in Embodiment two according to the present invention, wherein FIG. 2C is a top view, and FIG. 2D is also a structural diagram showing a pair of phase change memory cells in Embodiment two.

### DESCRIPTIONS OF COMPONENT MARK NUMBERS

1 Si substrate
21 a first dielectric material layer
22 a second dielectric material layer
23 a third dielectric material layer
31 a lower electrode layer
32 an upper electrode layer
4 a phase change material layer
5 a electrode pair
A window
W1 opening width of window
D a first thickness
W4 width of a phase change material layer
W5 width of a electrode pair

### DETAILED DESCRIPTION OF THE PREFERRED EMBODIMENTS

The implementation modes of the present invention will be described below through specific embodiments. One skilled in the art can easily understand other advantages and effects of the present invention according to content disclosed in the description. The present invention may also be implemented or applied through other different specific implementation modes. Various modifications or variations may be made to all details in the description based on different points of view and applications without departing from the spirit of the present invention.

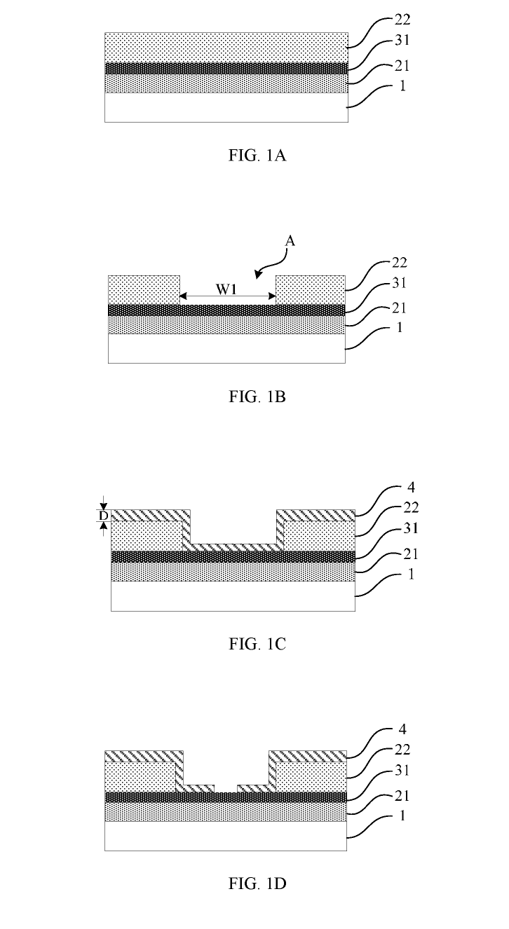

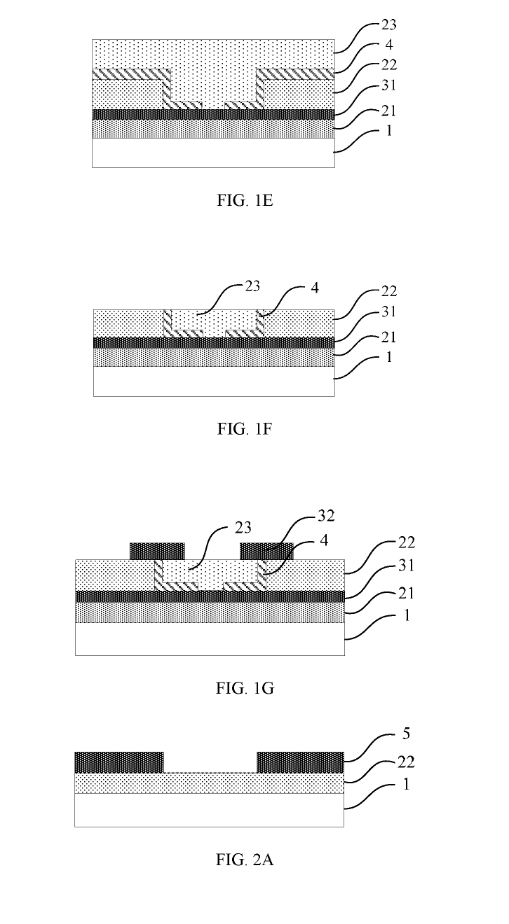

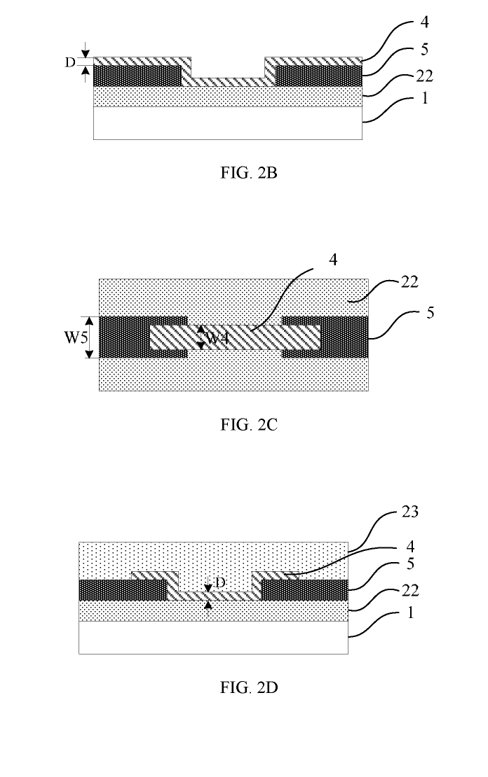

Please refer to FIGS. 1A to 2D. It should be noted that the drawings provided in the following specific embodiments only illustrate the basic concept of the present invention in a schematic manner. Only the components related to the present invention, rather than the actual number of components, shapes and the size of the drawing, are shown in the drawings. The configuration, number and size of each component during actual implementation thereof may be randomly changed, and the component layout configuration thereof may be more complex.

The main reason that the phase change memory loses efficacy is the reduced material uniformity result from element segregation of the phase change material. The element diffusion occurs mainly under high temperature conditions generated by current when operation. The longer the high temperature keeps, the serious the element segregation will be. Therefore, operating the phase change material in a high power for a long time will promote the element segregation, speed up device failure and reduce the number of recyclable operations. On the contrary, because the operation time of the phase change memory low power consumption and rapid operation is short, the segregation effect of the material for each operation is low, cycle times of the operation of the device will be improved.

In view of the above, the phase change memory cell and the preparation method thereof according to the present invention reduce the size of the three-dimensional phase change material in one dimension, such that the phase change material will substantially show the interfacial characteristics and the characteristics of body material will be weakened. The thickness of the phase change material layer used in the phase change memory cell according to the present invention is equal to the dimension of a single unit cell or a plurality of unit cells. On one hand, the phase change region is reduced. On the other hand, the characteristics of the body material of the phase change material layer are weakened. In addition, the reversible phase change behavior of the phase change material layer is focus on the interfacial characteristics. Therefore, the two-dimensional phase change memory cell having high density, low power consumption and high speed which stores information by using resistance variation of the interface is prepared. In the present invention, due to the thin phase change material layer and the small amount of defects at the interface of the phase change material layer, the operating power consumption of the phase change memory cell is reduced and the operation time is shortened, thereby reducing the damage to the phase change material during each operation. Thus, the element segregation effect on the material caused by each operation is reduced, and the maximum number of operation of the phase change memory cell is increased, thereby enhancing the cycle times of operation of the device. Further, the graphene electrode pair used in the present invention has features of fast signal response, high mechanical strength and less energy loss etc. Thus, the phase change memory cell based on graphene electrode pair has the advantages of high speed, low power consumption and long service life. The reversible phase change behavior of the small amount of unit cells of the phase change material layer in the present invention, the close and similar behaviors of amorphous basic unit and polycrystalline basic unit, the behavior of interface defects, the behavior of large difference between the metal and the phase change material in the amorphous and the polycrystalline resistances are compatible with the new kind of CMOS, and offers tremendous power in high speed, low power consumption under technical nodes of 10 nanometers. The embodiments of the phase change memory cell and the preparation method thereof according to the present invention will be described in detail below so that those skilled in the art can understand the phase change memory cell and the preparation method thereof according to the present invention without involving any creative work.

### Embodiment One

Referring to FIG. 1G the present invention provides a phase change memory cell comprising at least a Si substrate 1, a first dielectric material layer 21, a lower electrode layer 31, a second dielectric material layer 22, a phase change material layer 4, a third dielectric material layer 23 and an upper electrode layer 32.

The first dielectric material layer 21 is formed on a surface of the Si substrate. The lower electrode layer 31 is formed on a surface of the first dielectric material layer 21.

The upper surfaces of the second dielectric material layer 22, the phase change material layer 4 and the third dielectric material layer 23 are all located in the same plane; meanwhile, the second dielectric material layer 22, the phase change material layer 4 and the third dielectric material layers 23 are all formed on the lower electrode layer 31 and are in contact with the lower electrode layer 31.

The phase change material layer 4 has a first thickness D, and the phase change material layer 4 isolates the second dielectric material layer 22 from the third dielectric material layer 23. Further, as shown in FIG. 1G, in this embodiment, the cross sections of the phase change material layer 4 are two opposite L-shaped isolated by the third dielectric material layer 23, such that the phase change material layer 4 is divided into two portions, so as to respectively provide phase change material layers for a pair of phase change memory cells by way of one-to-one correspondence. Wherein one side of the L-shaped cross sections being in contact with the lower electrode layer 31 is a first side, and the other side of the L-shaped cross sections being perpendicular to the first side is a second side, the thicknesses of both the first side and the second side are a first thickness. Thus, FIG. 1G is a structural diagram showing a pair of phase change memory cells.

Wherein the first thickness D ranges from 6 angstrom to 60 angstrom, such that the phase change memory cell stores information by using the interface resistance difference of the phase change material layer. Further, the first thickness D ranges from 6 angstrom to 20 angstrom. In this embodiment, the first thickness D is preferably 15 angstrom.

The upper electrode layer 32 is in contact with the phase change material layer 4.

It should be noted that an operation signal is applied to the lower electrode layer 31 and the upper electrode layer 32 through wires to achieve the operation of the phase change memory cell, which is well known to those skilled in the art. Details thereof will not be described herein again.

As shown in FIG. 1A to FIG. 1G the present invention further provides a preparation method of the above phase change memory cell, including at least the following steps:

First, perform step 1). As shown in FIG. 1A, provide a Si substrate 1 having a first dielectric material layer 21 formed on its one surface. Then a lower electrode layer 31 and a second dielectric material layer 22 are successively deposited on the first dielectric material layer 21 from bottom to top. Wherein the first dielectric material layer 21 is an insulating dielectric material commonly used in semiconductor process, which includes at least one of silicon oxide, germanium oxide, gallium oxide, silicon nitride, germanium nitride, or gallium nitride. The thickness of the first dielectric material layer 21 ranges from 2 nm to 10 nm. The materials of the lower electrode layer 31 are selected from good conductors consisting of at least one of Cu, TiN, W, Ta, Ti, and Pt, or good conductor alloy consisting of at least one of the above. The second dielectric material layer 22 is a non-oxygen-containing insulating dielectric material commonly used in the semiconductor process, which includes at least any one of gallium nitride, germanium nitride, silicon nitride and the like.

In the present embodiment, the first dielectric material layer 21 is preferably silicon oxide having a thickness of 6 nm; the material of the lower electrode layer 31 is preferably TiN; and the second dielectric material layer 22 is preferably silicon nitride. Then perform step 2).

In step 2), as shown in FIG. 1B, a portion of the second dielectric material layer 22 is photo-etched and etched by processes of coating, exposing, etching, removing of photoresist and the like until the lower electrode layer 31 is exposed so as to form a window A, wherein the opening width W1 of the window A ranges from 10 nm to 100 nm. In the present embodiment, the opening width W1 of the window A is preferably 60 nm. Then perform step 3).

In step 3), as shown in FIG. 1C, a phase change material is deposited on the surface of the structure obtained in step 3) by a chemical vapor deposition (CVD) or atomic layer deposition (ALD) method to form a phase change material layer 4 having a first thickness D. Wherein the phase change material includes at least any one of Ge—Sb—Te, Ge—Te and Ti—Sb—Te. The phase change memory cells made up of the above three materials all have a good electrical performance. The first thickness D ranges from 6 nm to 60 nm, such that the phase change memory cell stores information by using interfacial resistance differences of the phase change material layer. Further, the first thickness D ranges from 6 angstrom to 20 angstrom. In the other two dimensional directions of the phase change material layer 4, the length of the phase change material layer 4 ranges from 50 angstrom to 100 angstrom, and the width of the phase change material layer 4 ranges from 50 angstrom to 100 angstrom.

In this embodiment, the phase change material is preferably Ti—Sb—Te. Preferably, the first thickness D is 15 angstrom. Preferably, the length of the phase change material layer 4 is 80 angstrom, and the width thereof is 80 angstrom. However, it is not limited to the case that the length and the width of the phase change material layer 4 are equal. In other embodiments, the length and the width of the phase change material layer may not be equal.

It should be noted that the conventional phase change material layer has a three-dimensional material size including length, width and thickness. In the present invention, the phase change material layer 4 reduces the size in one dimension of the three-dimensional material size. In this embodiment, the dimension corresponding to the small size of the phase change material layer 4 is thickness. Specifically, the thickness of the phase change material layer 4 is precisely controlled by adjusting the deposition time of the phase change material so that the thickness of the phase change material layer 4 is reduced to a first thickness equivalent to the dimension of the single unit cell or a plurality of unit cells, so that the thickness of the phase change material layer 4 can be neglected when the phase change material layer 4 is extremely thin, and the three-dimensional phase change material layer can be treated as a two-dimensional phase change material layer. The thin first thickness suppresses the formation of large crystal grain. Thus, on the one hand, the phase change region is reduced, which significantly reduces the operating power consumption of the phase change memory cell RESET operation. On the other hand, the properties of the body material of the phase change material layer are weakened, and the reversible phase change behavior of the phase change material layer is ensured to be mainly based interface characteristics. At this time, the interface characteristics are keys for the phase change memory cell to store information. Further, since the size of the phase change material is small, it is beneficial to reduce the size of the phase change memory cell, such that the phase change memory cell of the present invention has a potential of storing ultra-high density information.

It should be further explained that the smallest unit of the phase change material which can achieve the jump of Ge atoms before and after the phase change is a cube with a side length of about 6 angstrom. Therefore, in order to ensure the ability of repeated phase change of the phase change material, the thickness (i.e., the first thickness) of the phase change material layer 4 must be no less than 6 angstrom. At the same time, in order to ensure that the phase change material layer 4 reflects the characteristic that the interfacial effect is dominant, the thickness (i.e., the first thickness) of the phase change material layer 4 should be less than the size of ten minimum cells, i.e., 60 angstrom. Therefore, the thickness (i.e., the first thickness) of the phase change material layer 4 according to the present invention is controlled between 6 angstrom and 60 angstrom.

The influence of size effect on the thermal stability of a phase change material is as follows: when the thickness of the phase change material layer is more than 10 nm, the change of the crystallization temperature of the phase change material with the thickness is very weak. When the thickness of the phase change material layer is less than 10 nm, the crystallization temperature of the phase change material increases at different degrees with the decrease of the thickness. The thickness (i.e., the first thickness) of the phase change material layer 4 in this embodiment ranges from 6 angstrom to 60 angstrom, more preferably, ranges from 6 angstrom to 20 angstrom. Thus, the crystallization temperature of the phase change material layer 4 increases at different degrees with the reduction of the first thickness.

Meanwhile, the influence of size effect on the crystallization rate of phase change material is as follows: when the thickness of the phase change material is reduced, the specific surface area of the material is increased, and it is easy for the interface of the phase change material to form a unit cell due to the defects. The existence of the unit cell shortens the time for forming unit cell for the crystallization process of the phase transition material, and reduces the time required for the crystallization process, thereby enhancing the operating speed of the phase change memory. When the time for forming the unit cell is shortened, the growth of grain crystal becomes a major factor affecting the crystallization time, and the time for growing the grain crystal becomes shorter as the size decreases, which ensures the faster phase change speed of the small size device. Then perform step 4).

In step 4), as shown in FIG. 1D, photo-etching and etching processes including at least the processes of coating, exposing, etching and degreasing, or the focused ion beam FIB is used to remove a portion of the phase change material layer 4 on the lower electrode layer 31 until the lower electrode layer 31 located there-under is exposed. That is, a portion of the phase change material layer 4 in the window A and being in contact with the lower electrode layer 31 is removed to expose a portion of the lower electrode layer 31, such that the phase change material layer 4 is divided into two portions to respectively provide the phase change material layers for the phase change memory cells by way of one-to-one correspondence. As shown in FIG. 1D, in this embodiment, preferably, the symmetry axis of the removed portion of the phase change material layer is the center line of the window A, such that the phase change material layer 4 is bisected. Then perform step 5).

In step 5), as shown in FIG. 1E, a third dielectric material layer 23 is deposited on the surface of the structure obtained in step 4) by using low-temperature chemical vapor deposition or low-temperature atomic layer deposition to fill up the window A and simultaneously isolate the phase change material layer 4 that is divided into two portions in step 4). Wherein the third dielectric material layer 23 is an oxygen-free insulating dielectric material commonly used in semiconductor processes, and includes at least one of gallium nitride, germanium nitride and nitride Silicon. In the present embodiment, the third dielectric material layer 23 is preferably germanium nitride.

It should be noted that the reason that the second dielectric material layer 22 and the third dielectric material layer 23 do not contain oxygen is that the material contacting with the phase change material should not be an oxygen-containing material. In addition, since the second dielectric material layer 22 and the third dielectric material layer 23 are all in contact with the phase change material layer 4, the second dielectric material layer 22 and the third dielectric material layer 23 are oxygen-free insulating dielectric materials commonly used in semiconductor process.

It should be further noted that in the present invention, it is not limited whether the first dielectric material layer 21, the second dielectric material layer 22 and the third dielectric material layer 23 should be a consistent dielectric material. That is, the above three dielectric material layers may be the same or different, or they can be the same in pairs.

It should be noted that when depositing the third dielectric material layer 23 in the step 5), it is preferable to suppress the formation of defects at the interface between the third dielectric material layer 23 and the phase change material layer 4 to ensure that the interface is flat and therefore provide favorable conditions for lattice matching between the phase change material layer 4 and the third dielectric material layer 23. That is, a good interface is formed between the phase change material layer 4 and the third dielectric material layer 23. That is, there are a small amount of defects at the interface.

It should be noted that because the phase change material layer has a good interface, which ensures that the atoms of small percentage in the phase change material layer are stable during the reversible phase change process and further ensures that the components of the phase change material and the number of atoms remain stable and will not be oxidized during the reversible phase change process, such that the thermal stability of the phase change material layer is improved, and the phase change memory cell can work reliably at a higher working temperature. Since there are a small amount of defects at the interface of the phase change material layer, on the one hand, the lattice of the unit cell of the phase change material is distorted during polycrystalline, and under the thermal shock generated by the electric pulse, it is conducive to the transformation from polycrystalline to amorphous. At the same time, the formation of the unit cell of the phase change material during amorphous is easy. As a result, the effect of increasing the crystallization speed becomes more obvious, thereby effectively increasing the SET operation speed of the phase change memory cell. Then perform step 6).

In step 6), as shown in FIG. 1F, flattening the structure obtained in step 5) with a chemical mechanical polishing (CMP) process until the first dielectric material layer 21 and a portion of the phase change material layer 4 are exposed, such that the phase change material layer 4 has two opposite and non-contacted L-shaped cross sections. Then perform step 7).

In step 7), as shown in FIG. 1G; a upper electrode layer 32 covering the exposed phase change material layer 4 is formed to complete the preparation of two phase change memory cells. Specifically, in the present embodiment, the upper electrode layer 32 is deposited by using physical vapor deposition (PVD), low-temperature chemical vapor deposition or low-temperature atomic layer deposition; the upper electrode layer 32 is photo-etched and etched to form the upper electrode layer 32 covering the exposed phase change material layer 4.

Then, an operation signal is applied to the lower electrode layer 31 and the upper electrode layer 32 through wires to achieve the operation of the phase change memory cell. The unit driving device for realizing the reading/writing/erasing function of the phase change memory cell includes a transistor or a diode, such that the preparation process of the phase change memory cell is completely compatible with the CMOS process, wherein an 1T1R structure is formed when the unit driving device is a transistor, and an 1D1R structure is formed when the unit driving device is a diode. These contents are well known to those skilled in the art, and details will not be described herein again.

It should be noted that the reasons for suppressing the defects at the interface of the phase change material layer 4 and forming a good interface between the phase change material layer 4 and the third dielectric material layer 23 are as follows:

Due to lattice mismatch at the interface, defects are at the interface of the phase change material layer. The presence of defects can reduce the energy required for crystallization and shorten the nucleation time, thereby increasing the crystallization velocity of the phase change material. There are defects in unit cell at the interface of the phase change material, atomic structure ruptures or the bond energy is very small. It is easy to be ionized under the action of external force. Especially when the size of crystal grain is quite small, and the specific surface area thereof is very large. Thus, many atoms are ionized, and ions deviate from the original positions, which cause rapid changes in the structure. At the same time, the energy required for structural changes is reduced because of the presence of defects, thereby reducing the non-crystallizing power consumption of the phase change material.

However, the presence of excessive defects will make nucleation easier. The crystallization of the phase change material proceeds at a lower temperature, the thermal stability of the amorphous phase of the phase change material will decrease, thereby reducing the data retention of the phase change memory cell. When the size of the phase change material is as small as the dimension of one or a few unit cells, the presence of excessive defects at the interface will affect the formation of normal crystalline atomic structure in the phase change material, thereby resulting in a completely abnormal of atomic structure. Thus, the phase change material loses the ability to change phase reversibly. For the reasons given above, the defect density at the interface of the phase change memory cell prepared by the present invention should be controlled to a relatively small extent.

In order to enable those skilled in the art to further understand the present invention, relevant principles of the phase change memory cells will be described in detail below:

In the present invention, due to the thin phase change material layer, the total resistance stored in the phase change memory cell according to the present invention is mainly determined by the contact resistance (i.e., interface resistance) at the interface. The phase change memory cell controls the crystalline state and amorphous state of the phase change material, such that there is a huge difference among the contact resistances at the interface, the phase change memory cell reflects two distinctly different high and low resistances, thereby realizing data storage. Wherein sub-nanosecond electrical pulse signals are used to operate the phase change material in the phase change memory cell into amorphous state, and the interface between the electrode and the phase change material is in a high-resistance state, which is referred to as a RESET state. The sub-nanosecond electrical pulse signals are used to operate the phase change material in the phase change memory cell into crystalline state, and the interface between the electrode and the phase change material is in a low-resistance state, which is referred to as a SET state.

In this embodiment, the contact resistance at the interface between the phase change material in amorphous state and the electrode material is the first contact resistance, and the contact resistance at the interface between the phase change material in crystalline state and the electrode material is the second contact resistance, The specific value between the first contact resistance and the second contact resistance ranges from 10³ to 10⁵, wherein the electrode material includes an upper electrode layer and a bottom electrode layer.

With respect to the total resistance stored in the phase change memory cell, in this embodiment, the total resistance of the phase change memory cell in the RESET state is 10˜10 ⁵ times as that of the phase change memory cell in the SET state.

In the present invention, since the thickness of the phase change material is equivalent to the dimension of a single unit cell or a plurality of unit cells, a plurality of unit cell having a small size are formed when the amorphous state turns into crystalline state, which suppresses the formation of large crystal grains. Thus, it takes less distance and less time for atoms to migrate from disordered states to ordered states, which makes the phase change memory cell according to the present invention have an advantage of high speed. In the present invention, since the phase change material layer is thin, the phase change region is reduced. Therefore, the operating power consumption is reduced. Meanwhile, since the phase change material layer is thin, and there are a few defects at the interface of the phase change material layer, the operating speed is increased and the operating time is therefore shortened. All of the above reduce the damage to the phase change material during each operation, reduce the element segregation effect caused by each operation, and increase the maximum operable times of the phase change memory cell, which is benefit for improving the cycle number of the device.

In conclusion, the reversible phase change behavior of the small amount of unit cells of the phase change material layer according to the present invention, the close and similar behaviors of amorphous and polycrystalline basic units, the behavior of interface defects, the behavior of large difference between the metal and the phase change material in the amorphous and the polycrystalline resistances are compatible with the new kind of CMOS, and offer tremendous power in high speed, low power consumption under technical nodes of 10 nanometers.

### Embodiment Two

As shown in FIG. 2D, the present invention provides a phase change memory cell, including at least a Si substrate 1, a second dielectric material layer 22, an electrode pair 5, a phase change material layer 4, and a third dielectric material layer 23. FIG. 2D is a structural diagram illustrating a phase change memory cell in this embodiment.

The second dielectric material layer 22 is formed on the surface of the Si substrate 1. The second dielectric material layer 22 is an oxygen-free semiconductor dielectric material including at least one of gallium nitride, germanium nitride, and silicon nitride. In the present embodiment, the second dielectric material layer 22 is silicon nitride.

The electrode pair 5 is formed on the surface of the second dielectric material layer 22. There is a first distance between the two electrodes in the electrode pair 5, and the two electrodes are isolated from each other. The first distance ranges from 10 nm to 100 nm. In the present embodiment, the first distance is preferably 60 nm. The material of the electrode pair 5 includes metal or graphene. The metal includes at least one of Cu, TiN, W, Ta, Ti and Pt, or any one of the above-mentioned metal alloys. In this embodiment, preferably, the material of the electrode pair 5 is graphene.

The phase change material layer 4 has a first thickness D formed on the surface of the electrode pair 5 and the second dielectric material layer 22. At the same time, the width W4 of the phase change material layer 4 is less than or equal to the width W5 of the electrode pair 5. The width W4 of the phase change material layer 4 and the width W5 of the electrode pair 5 are shown in FIG. 2C. In this embodiment, the width of the phase change material layer 4 is preferably less than or equal to the width of the electrode pair 5; the first thickness D ranges from 6 angstroms to 60 angstroms, such that the phase change memory cells stores information by using interfacial resistance differences of the phase change material layer. Further, the first thickness D ranges from 6 angstroms to 20 angstroms. In the present embodiment, the first thickness D is preferably 15 angstroms.

When the width W4 of the phase change material layer 4 is less than the width W5 of the electrode pair 5, the third dielectric material layer 23 is formed on the surface of the phase change material layer 4 and the electrode pair 5, or when the width of the phase change material layer 4 W4 is equal to the width W5 of the electrode pair 5, the third dielectric material layer 23 is formed on the surface of the phase change material layer 4. In this embodiment, the third dielectric material layer 23 is formed on the surfaces of the phase change material layer 4 and the electrode pair 5. The thickness of the third dielectric material layer 23 ranges from 20 nm to 100 nm. That is, the distance between the surface of the third dielectric material layer 23 and the surface of the phase change material layer 4 is from 20 nm to 100 nm. In this embodiment, the thickness of the third dielectric material layer 23 is preferably 60 nm; the third dielectric material layer 23 is an oxygen-free semiconductor dielectric material including at least one of gallium nitride, germanium nitride, or silicon nitride. In this embodiment, the third dielectric material layer 23 is preferably germanium nitride.

It should be noted that an operation signal is applied to the electrode pair 5 through wires to achieve the operation of the phase change memory cell. This is well known to those skilled in the art, and details thereof will not be described herein again.

As shown in FIG. 2A to FIG. 2D, the present invention also provides a preparation method of the above phase change memory cell, at least including the following steps:

First, perform step 1). Provide a Si substrate 1 a second dielectric material layer 22 formed on its one surface, and an electrodes pair 5 is prepared on the second dielectric material layer 22. A distance between the electrode pair 5 is a first distance, which ranges from 10 nm to 100 nm; the material of the electrode pair 5 is metal or graphene, wherein the metal includes at least one of Cu, TiN, W, Ta, Ti and Pt, or any one of the above-mentioned metal alloys. The second dielectric material layer 22 is an oxygen-free insulating dielectric material commonly used in semiconductor processes, including at least one of gallium nitride, germanium nitride, or silicon nitride.

In this embodiment, the first distance is preferably in the range of 60 nanometers. The material of the electrode pair 5 is preferably graphene, but not limited thereto. In another embodiment, the material of the electrode pair 5 TiN may also be preferably TiN; and the second dielectric material layer 22 is preferably silicon nitride.

It should be pointed out that graphene is a new material having a single-layer lamellar structure composed of carbon atoms, and it has very low resistivity, very fast electron transfer rate, very stable structure of the olefin, extraordinary conductivity, strength of tens times more than steel and excellent light transmission. The electron mobility of graphene at room temperature exceeds 15000 cm²/V·s, and electrons migrate very efficiently. The electron mobilities of conventional semiconductors and conductors such as silicon, carbon nanotubes or copper are lower than that of graphene; the resistivity of graphene is only about 10⁻⁶ Ω·cm, which is lower than that of copper or silver, graphene is the material of the smallest resistivity in the world; the structure of graphene is very stable, the connections among the carbon atoms in the graphene is pliable and tough. When external force is applied to graphene, the carbon atoms thereof will be bended and deformed, so that the carbon atoms do not have to be rearranged to adapt to external forces so as to keep the structure stable, firm and hard. At the same time, due to the collision between electronic atoms and atomic atoms, the traditional semiconductors and conductors release some energy in the form of heat. The current computer chips waste 72%-81% of the electrical energy in this way. Different from the current computer chips, the electronic energy of graphene will not be depleted, and therefore graphene has extraordinary excellent characteristics. Therefore, the graphene used as an electrode pair in the present invention has the characteristics of fast signal response, high mechanical strength and low energy loss. Then perform step 2).

In step 2), as shown in FIG. 2B, a phase change material is deposited on the surface of the structure obtained in step 1) by chemical vapor deposition (CVD) or atomic layer deposition (ALD) to form a phase change material layer 4 having a first thickness D. The first thickness D ranges from 6 angstroms to 60 angstroms so that the phase change memory cell stores information by using the interfacial resistance difference of the phase change material layer. Further, the first thickness D ranges from 6 angstrom to 20 angstrom. In this embodiment, the first thickness D is preferably 15 angstrom.

It should be pointed out that the descriptions about the material type, the size and the beneficial effect of the phase change material layer 4 in step 2) according to this embodiment are basically the same as that of Embodiment one. Therefore, with respect to the same portions, please refer to descriptions of Embodiment one, and details thereof will be omitted. The difference is that the phase change material layer 4 in this embodiment is different from embodiment one in length and width sizes. Step 3) is then performed.

In step 3), as shown in FIG. 2C, the phase change material layer 4 having a width less than or equal to the width of the electrode pair 5 is formed by photo-etching and etching the phase material layer 4 through processes such as coating, exposure, etching and degumming, wherein the width W4 of the phase change material layer 4 and the width W5 of the electrode pair 5 are shown in FIG. 2C. Then step 4) is performed.

In step 4), as shown in FIG. 2D, a third dielectric material layer 23 is deposited on the surface of the structure obtained in step 3) by using low-temperature chemical vapor deposition or low-temperature atomic layer deposition, and the area between the electrode pair 5 is filled up. The thickness of the third dielectric material layer 23 ranges from 20 nm to 100 nm. In the present embodiment, the thickness of the third dielectric material layer 23 is preferably 60 nm. The third dielectric material layer 23 is oxygen-free semiconductor material including at least one of gallium nitride, germanium nitride and silicon nitride. In the present embodiment, the third dielectric material layer 23 is preferably germanium nitride.

It should be noted that the reason that the second dielectric material layer 22 and the third dielectric material layer 23 are oxygen-free dielectric materials can be found in embodiment one. Further, the present invention does not limit whether the second dielectric layer 22 and the third dielectric material layer 23 use the same material or not.

It should be further explained that when the third dielectric material layer 23 is deposited in step 4) according to this embodiment, it is preferable to suppress the formation of defects at the interface of the third dielectric material layer 23 and the phase change material layer 4 to ensure the smoothness of the interface, thereby providing favorable conditions for lattice matching between the phase change material layer 4 and the third dielectric material layer 23. That is, a good interface is formed between the phase change material layer 4 and the third dielectric material layer 23. That is, there is a small number of defects at the interface. For related descriptions of the reason for forming good interface characteristics and beneficial effects, please refer to the specific content disclosed in embodiment one.

It should be noted that the operation signal is applied to the electrode pair 5 through wires to achieve the operation of the phase change memory cell. The cell driving device for realizing the reading/writing/erasing function of the phase change memory cell includes a transistor or a diode, such that the preparation process of the phase change memory cell can be completely compatible with the CMOS process, wherein an 1T1R structure is formed when the single driving device is a transistor, and an 1D1R structure is formed when the unit driving device is a diode, which is well known to those skilled in the art, and details thereof will not be described herein again.

For details of the related principles of phase change memory cells and their beneficial effects, please refer to the related descriptions in Embodiment one.

To sum up, according to the phase change memory cell and the preparation method thereof in the present invention, the thickness of the used phase change material layer in the phase change memory cell is equal to the dimension of a single unit cell or a plurality of unit cell. On one hand, the phase change region is reduced, and on the other hand, the body material characteristics of the phase change material layer are weakened. In addition, the reversible phase change behavior of the phase change material layer is mainly focus on the interfacial characteristics. Therefore, the two-dimensional phase change memory cell having high density, low power consumption and high speed and storing information by using resistance variation of the interface is prepared. In the present invention, due to the thin phase change material layer and the small amount of defects on the interface of the phase change material layer, the operating power consumption of the phase change memory cell is reduced and the operation time is shortened, thereby reducing the damage to the phase change material during each operation. Thus, the element segregation effect on the material during each operation is reduced, the maximum number of operation of the phase change memory cell is increased, thereby enhancing the cycle numbers of operations of the device. Further, the graphene electrode used in the present invention has features of fast signal response, high mechanical strength and less energy loss. Thus, the phase change memory cell based on graphene electrode has the advantages of high speed, low power consumption and long service life. The reversible phase change behavior of the small amount of unit cells of the phase change material layer in the present invention, the close and similar behaviors of amorphous basic unit and polycrystalline basic unit, the behavior of interface defects, the behavior of large difference between the metal and the phase change material in the amorphous and the polycrystalline resistance are compatible with the new kind of CMOS, and offers tremendous power in high speed, low power consumption under technical nodes of 10 nanometers. Therefore, the present invention effectively overcomes various disadvantages in the prior art and has a high industrial value.

The above-mentioned implementation modes are just preferred implementation modes of the present invention. It shall be pointed out that one skilled in the art may make various improvements and replacements without departing from the technical principle of the present invention. However, these improvements and replacements shall be also considered as being included in the protection scope of the present invention.

1. A preparation method of phase change memory cell, characterized in that the preparation method at least comprises the following steps:
1) providing a Si substrate having a surface on which a first dielectric material layer is formed, and successively forming a lower electrode layer and a second dielectric material layer on the first dielectric material layer from bottom to top;
2) photo-etching and etching a portion of the second dielectric material layer until the lower electrode layer is exposed so as to form a window;
3) depositing a phase change material on a surface of the structure obtained in step 2) to form a phase change material layer having a first thickness;
4) removing a portion of the phase change material layer located on the lower electrode layer to divide the phase change material layer into two portions so as to respectively provide phase change material layers for a pair of phase change memory cells;
5) depositing a third dielectric material layer on a surface of the structure obtained in step 4) to simultaneously fill up the window and isolate the phase change material layer divided into two portions in step 4);
6) flattening the structure obtained in step 5) with a chemical mechanical polishing process until the first dielectric material layer and a portion of the phase change material layer are exposed, such that the phase change material layer has two opposite L-shaped cross sections;
7) forming an upper electrode layer covering the exposed phase change material layer.

2. The preparation method of phase change memory cell according to claim 1, characterized in that the thickness of the first dielectric material layer ranges from 2 nm to 10 nm.

3. The preparation method of phase change memory cell according to claim 1, characterized in that the opening width of the window ranges from 10 nm to 100 nm.

4. The preparation method of phase change memory cell according to claim 1, characterized in that the first thickness ranges from 6 angstrom to 60 angstrom, such that the phase change memory cell stores information by using the interfacial resistance difference of the phase change material layer.

5. The preparation method of phase change memory cell according to claim 4, characterized in that the first thickness ranges from 6 angstrom to 20 angstrom.

6. The preparation method of phase change memory cell according to claim 1, characterized in that the length of the phase change material layer ranges from 50 angstrom to 100 angstrom, and the width of the phase change material layer ranges from 50 angstrom to 100 angstrom.

7. The preparation method of phase change memory cell according to claim 1, characterized in that the phase change material comprises at least one of Ge—Sb—Te, Ge—Te and Ti—Sb—Te.

8. The preparation method of phase change memory cell according to claim 1, characterized in that the unit driving device for realizing the reading/writing/erasing function of the phase change memory cell comprises a transistor or a diode, wherein when the unit driving device is a transistor, an 1T1R structure is formed; when the unit driving device is a diode, an 1D1R structure is formed.

9. A phase change memory cell, characterized in that the phase change memory cell comprises:
a Si substrate;
a first dielectric material layer formed on a surface of the Si substrate;
a lower electrode layer formed on a surface of the first dielectric material layer;
a second dielectric material layer, a phase change material layer and a third dielectric material layer, all of which having upper surfaces located in a same plane, being formed on the lower electrode layer, and being in contact with the lower electrode layer, wherein the phase change material layer having a first thickness isolates the second dielectric material layer from the third dielectric material layer;
an upper electrode layer being in contact with the phase change material layer.

10. The phase change memory cell according to claim 9, characterized in that the phase change material layer has two opposite L-shaped cross sections isolated by the third dielectric material layer, wherein one side of the L-shaped cross sections being in contact with the lower electrode layer is a first side, and the other side of the L-shaped cross sections being perpendicular to the first side is a second side; the thicknesses of both the first side and the second side are the first thickness.

11. The phase change memory cell according to claim 9, characterized in that the first thickness ranges from 6 angstrom to 60 angstrom, such that the phase change memory cell stores information by using the interfacial resistance difference of the phase change material layer.

12. The phase change memory cell according to claim 11, characterized in that the first thickness ranges from 6 angstrom to 20 angstrom.

13. A preparation method of phase change memory cell, characterized in that the preparation method at least comprises the following steps:
1) providing a Si substrate having a surface on which a second dielectric material is formed, and preparing an electrode pair on the second dielectric material layer, wherein a distance between the electrode pair is a first distance;
2) depositing a phase change material on a surface of the structure obtained in step 1) to form a phase change material layer having a first thickness;
3) photo-etching and etching the phase change material layer to form a phase change material layer having a width less than or equal to the width of the electrode pair;
4) depositing a third dielectric material layer on a surface of the structure obtained in step 3) and filling up the area between the electrode pair.

14. The preparation method of phase change memory cell according to claim 13, characterized in that the first thickness ranges from 6 angstrom to 60 angstrom, such that the phase change memory cell stores information by using the interfacial resistance difference of the phase change material layer.

15. The preparation method of phase change memory cell according to claim 14, characterized in that the first thickness ranges from 6 angstrom to 20 angstrom.

16. The preparation method of phase change memory cell according to claim 13, characterized in that the first distance ranges from 10 nm to 100 nm.

17. The preparation method of phase change memory cell according to claim 13, characterized in that the thickness of the third dielectric material layer ranges from 20 nm to 100 nm.

18. The preparation method of phase change memory cell according to claim 13, characterized in that the material of the electrode pair is metal, metal alloy, metal nitride, or graphene.

19. A phase change memory cell, characterized in that the phase change memory cell comprises:
a Si substrate;
a second dielectric material layer formed on a surface of the Si substrate;
an electrode pair formed on a surface of the second dielectric material layer and having a first distance therebetween;
a phase change material layer formed on surfaces of the electrode pair and the second dielectric material layer, having a width less than or equal to the width of the electrode pair and having a first thickness; and
a third dielectric material layer formed on surfaces of the phase change material layer and the electrode pair, or formed on a surface of the phase change material layer.

20. The phase change memory cell according to claim 19, characterized in that the first thickness ranges from 6 angstrom to 60 angstrom, such that the phase change memory cell stores information by using the interfacial resistance difference of the phase change material layer.

21. The phase change memory cell according to claim 20, characterized in that the first thickness ranges from 6 angstrom and 20 angstrom.

22. The phase change memory cell according to claim 19, characterized in that the first distance ranges from 10 nm to 100 nm.

23. The phase change memory cell according to claim 19, characterized in that the thickness of the third dielectric material layer ranges from 20 nm to 100 nm.

24. The phase change memory cell of claim 19, characterized in that the material of the electrode pair is metal, metal alloy, metal nitride or graphene.
